(19) United States
(12) Patent Application Publication
(10) Pub. No.: US 2024/0182757 A1
(43) Pub. Date: Jun. 6, 2024

(54) Core-Shell Particle Die-Attach Material

(71) Applicant: Wolfspeed, Inc., Durham, NC (US)

(72) Inventors: Afshin Dadvand, Durham, NC (US); Devarajan Balaraman, Apex, NC (US)

(21) Appl. No.: 18/074,079

(22) Filed: Dec. 2, 2022

(51) Int. Cl. C09J 9/02; C09J 1/00; H01L 23/00

(52) U.S. Cl. CPC C09J 9/02; C09J 1/00; H01L 24/29; H01L 24/32; H01L 2224/2929; H01L 2224/29294; H01L 2224/29311; H01L 2224/29324; H01L 2224/29347; H01L 2224/29355; H01L 2224/29439; H01L 2224/29444; H01L 2224/29457; H01L 2224/29464; H01L 2224/2948; H01L 2224/29484; H01L 2224/32225; H01L 2224/32503

(57) ABSTRACT

Die-attach materials are provided. In one example, the die-attach material may include a plurality of core-shell particles. Each core-shell particle may include a core and a shell on the core. The core may include a conducting material. The shell may include an alloy. The alloy may include a first element and a second element. The second element may segregate into one or more grain boundaries in the die-attach material during bonding of the die-attach material.

### FIELD

The present disclosure relates generally to die-attach materials.

### BACKGROUND

Semiconductor devices, including power semiconductor devices based on wide band gap materials, may be formed on a semiconductor wafer as part of a semiconductor fabrication process. The semiconductor wafer may be diced into many individual pieces, each containing one or more semiconductor devices. Each of these pieces may be a semiconductor die. The semiconductor die may need to be attached to other components as part of packaging of the semiconductor device. For instance, a semiconductor die, such as a wide band gap semiconductor die, may need to be attached to a conductive lead frame for use in a power discrete package or a power module. Materials used to attach the semiconductor die to other components may need to provide a thermal, mechanical, and/or electrical connection of the semiconductor die to the other components.

### SUMMARY

Aspects and advantages of embodiments of the present disclosure will be set forth in part in the following description, or may be learned from the description, or may be learned through practice of the embodiments.

One example aspect of the present disclosure is directed to a die-attach material. The die-attach material may include a plurality of core-shell particles. Each core-shell particle may include a core and a shell on the core. The core may include a conducting material. The shell may include an alloy. The alloy may include a first element and a second element. The second element may segregate into one or more grain boundaries in the die-attach material during bonding of the die-attach material.

Another example aspect of the present disclosure is directed to a die-attach material. The die-attach material includes a plurality of core-shell particles. Each core-shell particle may include a core and a shell on the core. The core may include a conducting material. The shell may include an alloy. The alloy may include one or more of tungsten (W), cobalt (Co), or molybdenum (Mo).

Another example aspect of the present disclosure is directed to a device. The device may include a die including a wide band gap semiconductor material. The device may include a substrate. The device may include a die-attach material between the die and the substrate. The die-attach material may include a plurality of core-shell particles. Each core-shell particle may include a core and a shell on the core. The core may include a conducting material and the shell may include an alloy. The alloy may include one or more of tungsten (W), cobalt (Co), or molybdenum (Mo).

Another example aspect of the present disclosure is directed to a device. The device may include a substrate. The device may include a sintered material on the substrate. The sintered material may include a plurality of core-shell particles. Each core-shell particle may include a core and a shell on the core. The core may include a conducting material and the shell may include an alloy. The alloy may include a complementary element segregated into one or more grain boundaries of the sintered material.

Another example aspect of the present disclosure is directed to a method. The method may include depositing a die-attach material on a substrate. The die-attach material may include a plurality of core-shell particles. Each core-shell particle may include a core and a shell on the core. The core may include a conducting material and the shell may include an alloy. The alloy may include one or more of tungsten (W), cobalt (Co), or molybdenum (Mo). The method may include bonding the die-attach material.

Another example aspect of the present disclosure is directed to a method. The method may include adding a second solution to a first solution. The first solution may include a core particle. The second solution may include a shell precursor and a complementary element precursor to form a shell on the core particle. The shell may include an alloy. The alloy may include tungsten (W), cobalt (Co), or molybdenum (Mo).

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts an example device with a semiconductor die attached to a substrate using a die-attach material according to example embodiments of the present disclosure;

FIG. 2 depicts core-shell particles of a die-attach material according to example embodiments of the present disclosure;

FIG. 3 depicts an example semiconductor device according to example embodiments of the present disclosure;

FIG. 4 depicts an example device using a die-attach material to form an antenna according to example embodiments of the present disclosure;

FIG. 5 depicts an example device using a die-attach material to form an interconnect according to example embodiments of the present disclosure;

FIG. 6 depicts a flow chart of an example method according to example embodiments of the present disclosure;

FIG. 7 depicts a flow chart of an example method according to example embodiments of the present disclosure; and

FIG. 8 depicts a flow chart of an example method according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Example aspects of the present disclosure are directed to die-attach materials for use in semiconductor applications and other electronics applications, such as wide band gap semiconductor device applications. Various technologies that are practiced in the semiconductor industry for die-attach present challenges and limitations. For example, semi-silver or full-silver sintering process techniques offer acceptable electrical, mechanical and thermal properties for die-attach applications. However, semi-silver or full-silver sintering process techniques may have a high cost and also may be at high risk of electromigration, high voiding/porosity, and high thermo-mechanical stresses. Eutectic Au80Sn20 techniques may also pose similar limitations. Semi-sintered or full-sintered copper is a lower cost option with somewhat lower performance, but also with some challenges in storage as well as in the deposition process, which may require a low temperature and a forming gas. Lead (Pb) based die-attach solutions are not optimal options for achieving low thermal resistance and efficient current or power density. In addition, lead (Pb) based die-attach materials do not meet certain lead-free certification standards.

Example aspects of the present disclosure are directed to a core-shell particle-based die-attach material. The die-attach material may include a paste-based or ink-based material including a plurality of metal core-shell microparticles and/or metal core-shell nanoparticles dispersed in a solution or grafted to a polymer matrix to form a metal-filled composite material.

The structure of the core-shell particles may include a core of a conducting material (e.g., electrically conducting material), such as copper (Cu), tin (Sn), aluminum (Al), or nickel (Ni). The core-shell particle may include a shell on the core. The shell may include an alloy. The alloy may include a first element and a second element. In example embodiments, the first element of the alloy may be a conductive element, such as silver (Ag), gold (Au), or palladium (Pd). The second element (e.g., also referred to as a complementary element) may segregate into grain boundaries of the die-attach material during bonding of the die-attach material. In some embodiments, the second element may be tungsten (W), cobalt (Co), or molybdenum (Mo). For instance, the alloy may be silver-cobalt alloy (AgCo), silver-tungsten alloy (AgW), and/or silver-molybdenum alloy (AgMo).

The shell may reduce or prevent oxidation of the core. The shell may enhance particle-to-particle contact after bonding to reduce voids in the die-attach material. In some examples, the die-attach material may form an intermetallic compound after bonding of the die-attach material to reduce passage of an electro-migrating metal in the die-attach material.

Aspects of the present disclosure are discussed with reference to a die-attach material for attaching a semiconductor die (e.g., a silicon carbide-based semiconductor die, Group III nitride-based semiconductor die, silicon-based semiconductor die, etc.) to a substrate or other component for purposes of illustration and discussion. Those of ordinary skill in the art, using the disclosures provided herein, will understand that the materials provided herein may be used to provide attachment of any suitable components without deviating from the scope of the present disclosure. In this regard, the term “die-attach material” in the disclosure and claims is intended to refer to any material that is used to provide thermal, electrical, and/or mechanical connection between two components.

In some examples, the core-shell particles may be dispersed in a solution to form the die-attach material as an ink or a paste. For instance, in some embodiments, the core-shell particles may be dispersed in ethylene glycol. In some embodiments, the core-shell particles may be grafted to a polymer matrix to form the die-attach material as an ink or a paste.

The die-attach material may be deposited on a substrate. A semiconductor die or other component may be placed on the die-attach material. The die-attach material may be subjected to bonding or a bonding process (e.g., sintering) to secure the semiconductor die or other component to the die-attach material. As used herein, the term “bonding” or “bonding process” refers to causing a transition of a material from a first form to a second form. A bonding process may or may not require attaching a component to the material. Sintering, reflow, annealing, curing, exposing to light, and exposing to ultraviolet light are examples of bonding processes and are encompassed by the term “bonding” or “bonding process” in the disclosure and in the claims.

In some embodiments, the shell may be formed on the core (e.g., plated on the core) using an electroless process. The electroless process may include cleaning, sensitization/activation, and deposition. The activation may be accomplished through the immersion of core particles in a solution containing a mixture of, for instance, stannous chloride (SnCl₂) and palladium chloride (PdCl₂).

In some embodiments, the core-shell particle may be formed, for instance, by adding a second solution to a first solution. The first solution may include core particles and/or a core precursor to form the core particles. Example core precursors may include: copper sulfate (CuSO₄), copper nitrate (Cu(NO₃)₂), copper chloride (CuCl₂), copper acetate (Cu(CO₂CH₃)₂), nickel acetate (Ni(CH₃CO₂)₂), nickel sulfate (NiSO₄), etc.

The second solution may include a shell precursor and a complementary element precursor to form a shell on the core particles. Example shell precursors may include: silver nitrate (AgNO₃), chloroauric acid (H(AuCl₄)), palladium nitrate (Pd(NO₃)₂), palladium sulfate (PdSO₄), etc. Example complementary element precursors may include: sodium tungstate dihydrate (Na₂WO₄), tungsten (VI) nitrate (W(NO₃)₆), cobalt nitrate (Co(NO₃)₂), cobalt sulfate (CoSO₄), sodium molybdate (Na₂MoO₄), etc.

Aspects of the present disclosure provide a number of technical effects and benefits. For instance, die-attach materials according to example embodiments of the present disclosure may provide enhanced aging stability, lower defects and voids, lower risk of electromigration and/or higher thermal, mechanical, and electrical properties compared to that of core-only or other core-shell particles. It is also a lead-free approach and may meet certain lead-free certification standards.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation of the scope set forth in the following claims.

With reference now to the Figures, example embodiments of the present disclosure will now be set forth.

FIG. 1 depicts a cross-sectional view of a semiconductor device 100 according to example embodiments of the present disclosure. The semiconductor device 100 may include a substrate 102. The substrate 102 may be, for instance, a lead frame or other supporting structure of a wide band gap power semiconductor device, such as a silicon carbide-based semiconductor power module or discrete package. The substrate 102 may be, for instance, a copper substrate 102 or may include other suitable conducting material(s).

The semiconductor device 100 may include a semiconductor die 104. The semiconductor die 104 may include one or more devices, such as one or more of a wide variety of power devices available for different applications including, for example, power switching devices and/or power amplifiers. In some examples, the semiconductor die 104 may include one or more field effect transistors (FETs) devices, including MOSFETs (metal-oxide semiconductor field-effect transistors), DMOS (double-diffused metal-oxide semiconductor) transistors, HEMTs (high electron mobility transistors), MESFETs (metal-semiconductor field-effect transistors), LDMOS (laterally diffused metal-oxide semiconductor) transistors, etc. In some embodiments, the semiconductor die 104 may include one or more diodes (e.g., Schottky diodes, light emitting diodes, etc.).

In some embodiments, the semiconductor die 104 may be fabricated from wide band gap semiconductor materials (e.g., having a band gap greater than 1.40 eV). For high power, high temperature, and/or high frequency applications, devices formed in wide band gap semiconductor materials such as silicon carbide (e.g., 2.996 eV band gap for alpha silicon carbide at room temperature) and the Group III-nitrides (e.g., 3.36 eV band gap for gallium nitride at room temperature) may provide higher electric field breakdown strengths and higher electron saturation velocities.

Aspects of the present disclosure are discussed with reference to wide band gap semiconductors for purposes of illustration and discussion. Those of ordinary skill in the art, using the disclosures provided herein, will understand that the die-attach materials according to example embodiments of the present disclosure may be used with any semiconductor material or other material without deviating from the scope of the present disclosure.

The semiconductor die 104 may be attached to the substrate 102 using a die-attach material 106. The die-attach material 106 may include a plurality of core-shell particles. The particles may be nucleocapsid particles. Nucleocapsid particles refers to particles having a core (e.g., nucleus) that is encompassed by shell material. The die-attach material 106 may be subjected to a bonding process to mechanically, thermally, and/or electrically connect the semiconductor die 104 to the substrate 102.

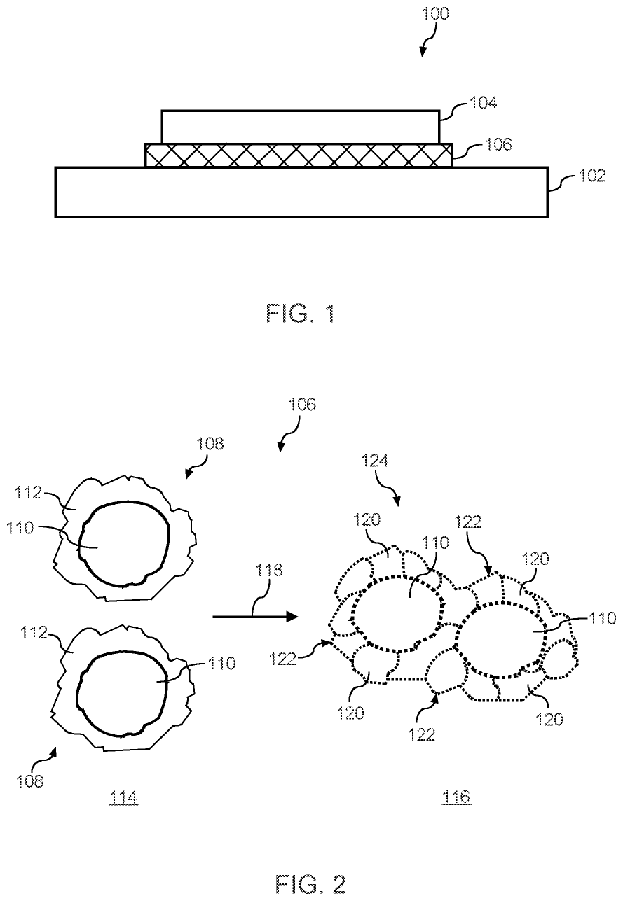

FIG. 2 depicts aspects of the die-attach material 106 according to example embodiments of the present disclosure. The die-attach material 106 may include a plurality of core-shell particles 108. Each core-shell particle 108 may include a core 110 and a shell 112 on the core 110. The core 110 may be a conducting material (e.g., an electrically conducting material). In some examples, the core 110 may include a metal, a metal-oxide, a ceramic material, or an organic material. In some examples, the conducting material of the core 110 may include copper (Cu), tin (Sn), aluminum (Al), or nickel (Ni).

The shell 112 may include a material having a first element that is conducting and a second element that segregates into grain boundaries of the die-attach material 106 after bonding of the die-attach material 106. The shell 112 may reduce or prevent oxidation of the core 110. In some embodiments, the shell 112 may include a metal-oxide, ceramic, or organic material. In some embodiments, the shell 112 may include an alloy, such as a metal alloy. The first element of the alloy may be silver (Ag), gold (Au), palladium (Pd), or other suitable metal. The second element of the alloy may have limited solubility in the shell 112 (e.g., no solubility in the shell 112) to efficiently segregate into grain boundaries of the die-attach material 106 without requiring high temperatures (e.g., greater than about 200)° ° C. For instance, the second element of the alloy may be tungsten (W), cobalt (Co), or molybdenum (Mo).

In some embodiments, the core 110 may include copper (Cu) and the shell 112 may be a silver-tungsten (AgW) alloy with silver (Ag) as the first element and tungsten (W) as the second element. In some embodiments, the core 110 may include copper (Cu) as the conducting material and the shell 112 includes a silver-cobalt (AgCo) alloy with silver (Ag) as the first element and cobalt (Co) as the second element. In some embodiments, the core 110 may include copper (Cu) as the conducting material and the shell 112 includes a silver-molybdenum (AgMo) alloy with silver (Ag) as the first element and molybdenum (Mo) as the second element.

In some embodiments, the core-shell particles 108 may be nanoparticles. For instance, the core 110 of each of the core-shell particles 108 may have a size of less than about 1 μm.

In some embodiments, the core-shell particles 108 may be microparticles. For instance, the core 110 of each of the core-shell particles 108 may have a size in a range of 1 μm to about 50 μm.

In some examples, the core-shell particles 108 may be dispersed in a solvent or other media to provide a metal-filled composite that has a form of an ink or a paste prior to bonding. The solvent may be, for instance, ethylene glycol. In some examples, the core-shell particles 108 may be mixed with or grafted to a polymer matrix to form an ink or a paste prior to bonding. The conductive ink or conductive paste may be deposited (e.g., deposited on substrate 102 of FIG. 1), using inkjet, dispense, screen printer, flexo printer, gravure printer, spin coater, blade coater, spray coater, or other deposition technique(s). The die-attach material 106 may be subjected to a bonding process to transition the die-attach material 106 from a first form to a second form.

FIG. 2 depicts the transition of die-attach material from a first form 114 to a second form 116 as a result of bonding 118 of the die-attach material. The bonding 118 may include sintering, reflow, annealing, curing, exposure to light, exposure to ultraviolet light, exposure to a laser, exposure to pulsed light, or other suitable process to transition the form of the die-attach material 106. In the example of FIG. 2, the bonding 118 may include sintering to form a sintered material.

As shown in FIG. 2, after bonding 118, the first element 120 of the shell 112 is disposed around the core(s) 110 of the core-shell particles 108. The first element 120 of the shell 112 may be, for instance, silver (Ag), gold (Au), palladium (Pd). The second element 122 (represented by dotted lines) is segregated into grain boundaries of the die-attach material 106. The second element 122 may be, for instance, tungsten (W), cobalt (Co), or molybdenum (Mo). The die-attach material 106, after bonding 118, may form an intermetallic compound 124. The intermetallic compound 124 may reduce passage of an electro-migrating metal (e.g., copper) in the die-attach material 106 after bonding 118 of the die-attach material 106.

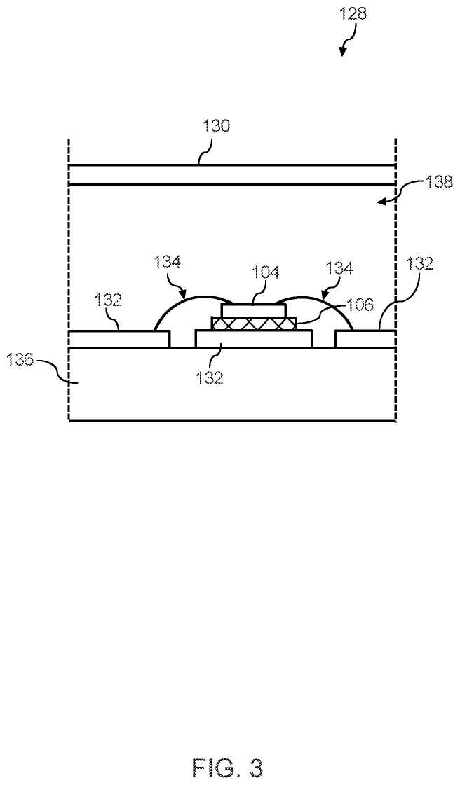

FIGS. 3-5 depict example devices including a die-attach material according to example embodiments of the present disclosure. FIGS. 3-5 are provided for purposes of illustration and discussion. Those of ordinary skill in the art, using the disclosures provided herein, will understand that the die-attach material may be used in a variety of devices and/or applications without deviating from the scope of the present disclosure

FIG. 3 depicts a cross-sectional view of a portion of a power module 128 according to example embodiments of the present disclosure. FIG. 3 is intended to represent structures for identification and description and is not intended to represent the structures to physical scale. The power module 128 may include a housing 130. The power module 128 may include a conductive substrate 132 (e.g., a patterned conductive substrate) on which a semiconductor die 104 containing one or more power devices (e.g., transistors, diodes, etc.) is attached using the die-attach material 106 according to example embodiments of the present disclosure. The die-attach material 106 may provide a thermal, mechanical, and electrical connection between the semiconductor die 104 and the conductive substrate 132. In some embodiments, the semiconductor die 104 may also be connected to the conductive substrate 132 using wire bonds 134. The conductive substrates 132 may be mounted on a base layer 136 (e.g., an insulating layer). An inert gel 138 may fill the space between the semiconductor die 104 and the housing 130.

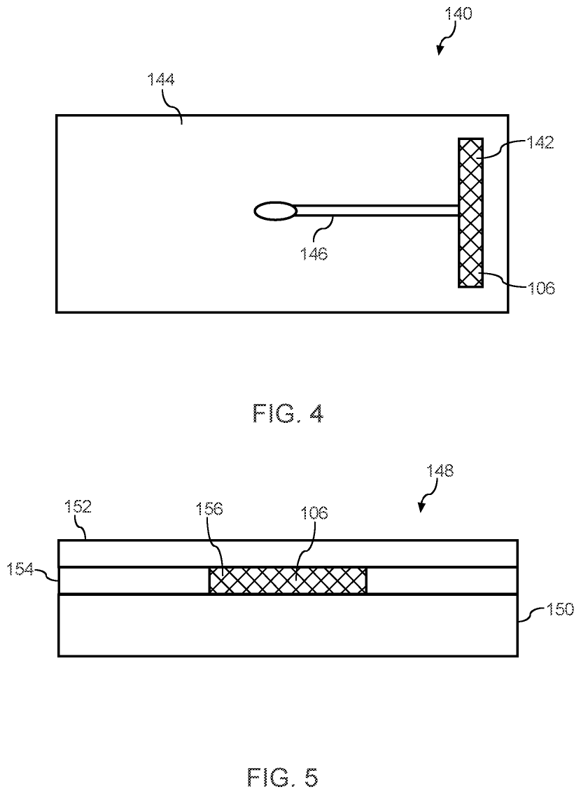

FIG. 4 depicts a device 140 incorporating a die-attach material to form an antenna 142 for the device according to example embodiments of the present disclosure. More particularly, the device 140 may include a substrate 144, such as a dielectric substrate 144. The dielectric substrate 144 may have one or more conductive elements 146, such as one or more circuit traces forming a transmission line and/or a mounting connection for the antenna 142. The die-attach material 106 may be deposited on the substrate 144 using inkjet, screen printer, flexo printer, gravure printer, spin coater, blade coater, spray coater, or other deposition technique(s). The die-attach material 106 may be subjected to a bonding process to form the antenna 142 on the substrate 144.

FIG. 5 depicts a cross-sectional view of at least a portion of a device 148 incorporating a die-attach material 106 to form an interconnect for the device 148 according to example embodiments of the present disclosure. FIG. 5 is intended to represent structures for identification and description and is not intended to represent the structures to physical scale. The device 148 may include a first layer 150 having one or more conductive portions or other portions requiring a thermal and/or electrical connection. The device 148 may include a second layer 152 that is spaced apart from the first layer 150. The second layer 152 may have one or more conductive portions or other portions requiring a thermal and/or electrical connection. The device 148 may include a third layer 154 (e.g., an insulating layer) disposed between the first layer 150 and the second layer 154. The insulating layer 154 may be patterned. The die-attach material 106 may be deposited in or on the insulating layer (e.g., in one or more voids in a patterned insulating layer 154) and subjected to a bonding process to form an interconnect 156 for the device 148. The interconnect 156 may electrically and/or thermally connect one or more portions of the first layer 150 with one or more portions of the second layer 152.

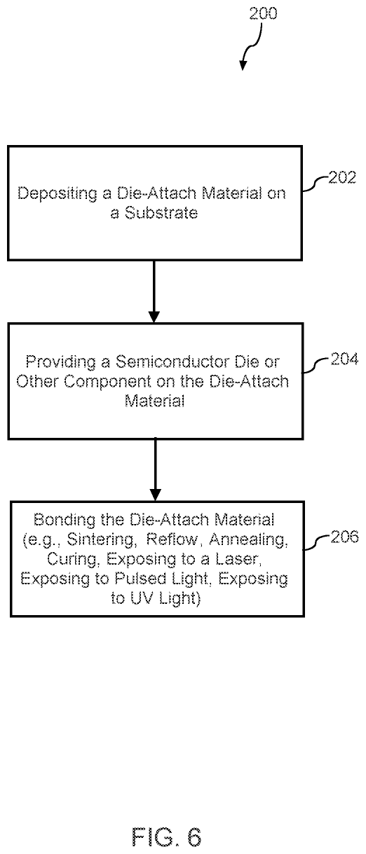

FIG. 6 depicts a flow chart of an example method 200 according to example embodiments of the present disclosure. FIG. 6 depicts example method steps for purposes of illustration and discussion. Those of ordinary skill in the art, using the disclosures provided herein, will understand that the methods described in the present disclosure may be adapted, modified, include steps not illustrated, omitted, and/or rearranged without deviating from the scope of the present disclosure.

At 202, the method may include depositing a die-attach material on a substrate. The die-attach material may be any of the example die-attach materials discussed herein. For instance, the die-attach material may be the die-attach material 106 discussed with reference to FIGS. 1 and 2. In some embodiments, the die-attach material may be deposited on the substrate using inkjet, screen printer, flexo printer, gravure printer, spin coater, blade coater, spray coater, or other deposition technique(s).

At 204, the method may include providing a semiconductor die or other component on the die-attach material. In some examples, the semiconductor die may include a wide band gap semiconductor die. For instance, the semiconductor die may include a silicon carbide-based semiconductor and/or a Group III nitride-based semiconductor. The semiconductor die may include one or more devices, such as one or more transistors, one or more diodes, or other devices.

At 206, the method may include bonding the die-attach material to attach the semiconductor die to the substrate. Bonding may include subjecting the die-attach material to any bonding process, such as sintering, reflow, annealing, curing, exposing to a laser, exposing to pulsed light, exposure to ultraviolet radiation, or other process.

In one example, bonding may include sintering the die-attach material by exposing the die-attach material to heat and/or pressure. For instance, sintering the die-attach material may include heating the die-attach material to a temperature in a range of about 100° C. to about 400° C., such as about 150° ° C. to about 300° C., for about 30 min to about 120 min. The temperature may be selected so as not to liquify or cause reflow of the die-attach material. Sintering the die-attach material may also include subjecting the die-attach material to pressure by applying a force onto the semiconductor die. The force may be applied by applying a flat punch or other tool to the semiconductor die. The pressure may be in a range of 1 MPa to about 30 MPa, such as about 5 MPa to about 25 MPa, such as about 10 MPa to about 20 MPa. The pressure may be applied to a time period in a range of about 1 minute to about 15 minutes. Sintering the die-attach material may cause a complementary element (e.g., tungsten (W), cobalt (Co), or molybdenum (Mo)) of a shell of the core-shell particles to segregate into grain boundaries of the sintered die-attach material.

Other example bonding processes may be performed on the die-attach material without deviating from the scope of the present disclosure. For instance, in some embodiments, the die-attach material may be exposed to a laser. In some embodiments, the die-attach material may be subjected to a reflow process. In some embodiments, the die-attach material may be exposed to high intensity pulsed light. In some embodiments, the die-attach material may be exposed to ultraviolet light.

Synthesis of the core-shell particles may use a precursor of the core, the shell, the complementary element, a stabilizer/complexing agent, a solvent, and/or a reducing agent. In some examples, the core may be metal, metal oxide, ceramic or organic material. The shell may also be metal oxide, ceramic or organic. The complementary element may have no solubility or may have limited solid solubility in the shell to be able to efficiently segregate to the grain boundaries, for example, in absence of a high temperature condition. The complementary element may be tungsten (W), cobalt (Co), or molybdenum (Mo).

In some examples, the redox potential of the core is lower than the oxidizer (e.g., the shell and complementary element). Otherwise, the reduction may be slow or there will be no reduction. In some examples, the limitation posed by the redox potential may be solved by using appropriate complexing agents. For example, using thiourea to adjust the deposition potential of copper (Cu) and tin (Sn) and to develop a copper core—tin shell structure.

Examples of a core precursor may include one or more of: copper sulfate (CuSO₄), copper nitrate (Cu(NO₃)₂), copper chloride (CuCl₂), copper acetate (Cu(CO₂CH₃)₂), nickel acetate (Ni(CH₃CO₂)₂), nickel sulfate (NiSO₄), etc.

Examples of a shell precursor may include one or more of: silver nitrate (AgNO₃), chloroauric acid (H(AuCl₄)), palladium nitrate (Pd(NO₃)₂), palladium sulfate (PdSO₄), etc.

Examples of a complementary element (e.g., second element of the metal alloy) precursor may include one or more of: sodium tungstate dihydrate (Na₂WO₄), tungsten(VI) nitrate (W(NO₃)₆) cobalt nitrate (Co(NO₃)₂), cobalt sulfate (CoSO₄), sodium molybdate (Na₂MoO₄), etc.

Examples of a stabilizer may include one or more of: polyvinylpyrrolidone (PVP), cetyltrimethylammonium-bromide (CTAB), ethylenediamin (EDA), dimethylhydentoine (DMH), etc.

Examples of a reducing agent may include one or more of: ethylene glycol (EG), sodium borohydride (NaBH₄), Monosodium phosphate (NaH₂PO₄), glucose (C₆H₁₂O₆), dimethylamine-borane (DMAB), ascorbic acid (C₆H₈O₆), and PVP, etc.

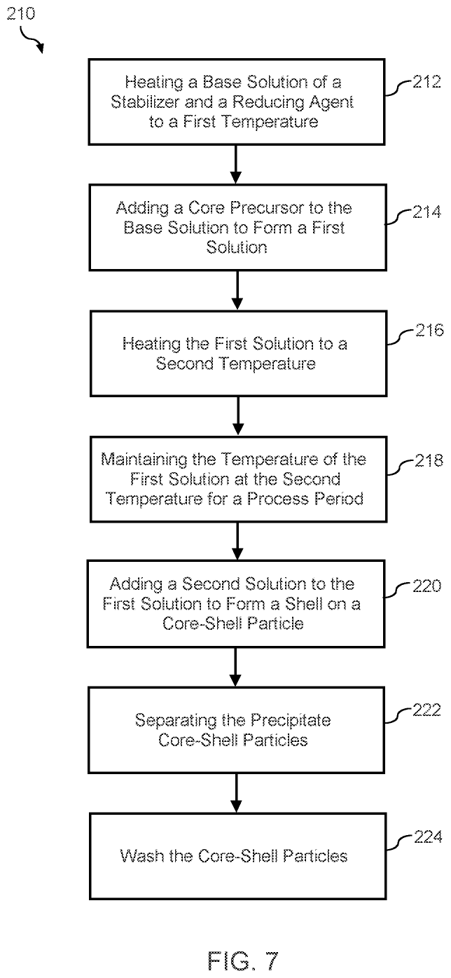

FIG. 7 depicts a flow diagram of an example method 210 of forming the core-shell particles (e.g., core-shell nanoparticles) of the die-attach material according to example embodiments of the present disclosure. FIG. 7 depicts example method steps for purposes of illustration and discussion. Those of ordinary skill in the art, using the disclosures provided herein, will understand that the methods described in the present disclosure may be adapted, modified, include steps not illustrated, omitted, and/or rearranged without deviating from the scope of the present disclosure.

Referring to FIG. 7 at 212, the method 210 may include heating a base solution of a stabilizer and a reducing agent to a first temperature. The first temperature may be in a range of about 50° ° C. to about 100° C. At 214, the method 210 may include adding a core precursor to the base solution to form a first solution. Examples of a core precursor may include: copper sulfate (CuSO₄), copper nitrate (Cu(NO₃)₂), copper chloride (CuCl₂), copper acetate (Cu(CO₂CH₃)₂), nickel acetate (Ni(CH₃CO₂)₂), nickel sulfate (NiSO₄), etc.

At 216, the method 210 may include heating the first solution with the core precursor to a second temperature. The second temperature may be in a range of about 100° C. to about 175° C. At 218, the method 210 may include maintaining the first solution at about the second temperature for a process period to form the core. The process period may be in a range of about 5 minutes to about 30 minutes.

At 220, the method 210 may include adding a second solution to the first solution to form a shell on the core. The second solution may include the shell precursor and the complementary element precursor. Examples of a shell precursor may include silver nitrate (AgNO₃), chloroauric acid (H(AuCl₄)), palladium nitrate (Pd(NO₃)₂), palladium sulfate (PdSO₄), etc. Examples of a complementary element (e.g., second element of the metal alloy) precursor may include: sodium tungstate dihydrate (Na₂WO₄), tungsten(VI) nitrate (W(NO₃)₆) cobalt nitrate (Co(NO₃)₂), cobalt sulfate (CoSO₄), sodium molybdate (Na₂MoO₄), etc. The second solution may be added to the first solution at a flow rate. The flow rate may be in range of about 1 mL/min to about 5 mL/min. The solution may be stirred for a second process period. The second process period may be in a range of about 3 minutes to about 45 minutes. The resulting precipitate may include the core-shell particles.

At 222, the core-shell particles may be separated from the solution, for instance, using a centrifuge. At 224, the core-shell particles may be washed, for instance, with deionized water or ethanol.

Examples of forming core-shell particles using the example method 210 of FIG. 7 are provided below:

### Example 1

Copper Core with Silver-Tungsten Alloy Shell

A solution of PVP in EG (0.5-1 mM) is heated (50° C. to 100° C.) under air or under the purge of an inert gas (e.g., Ar/N₂). A solution of Cu(CO₂CH₃)₂ in EG is added and temperature is increased to 150° C. for a certain time (depending on the desired size of the core, for example 5 to 30 min) to form copper core particles. This is followed by slow addition (e.g., 1-5 mL/min) of (e.g., 1-20 mM) solution of mixed AgNO₃ and Na₂WO₄ in EG and stirred for another 5-30 min. The precipitate containing the core-shell particles with copper core and silver-tungsten alloy shell is separated by centrifuge and washed with deionized water.

### Example 2

Copper Core with Silver-Cobalt Alloy Shell

Copper (Cu) core particles are obtained by the reduction of CuSO₄ in a solution of NaH₂PO₄ as reducing agent and also with DMH as a stabilizer and citric acid as a complexing agent in deionized water at a temperature of 50° C. to 80° C. and pH of 5.5 to 6.5 (adjusted using NaOH) and stirred for a certain time (e.g., 30-60 min). A solution of mixed AgNO₃ and Co(NO₃)₂ in EG is slowly added to the mixture (e.g., 1-5 mL/min) and stirred for another 30-60 min. The precipitate containing the core-shell particles with copper core and silver-cobalt alloy shell is separated by centrifuge and washed with deionized water.

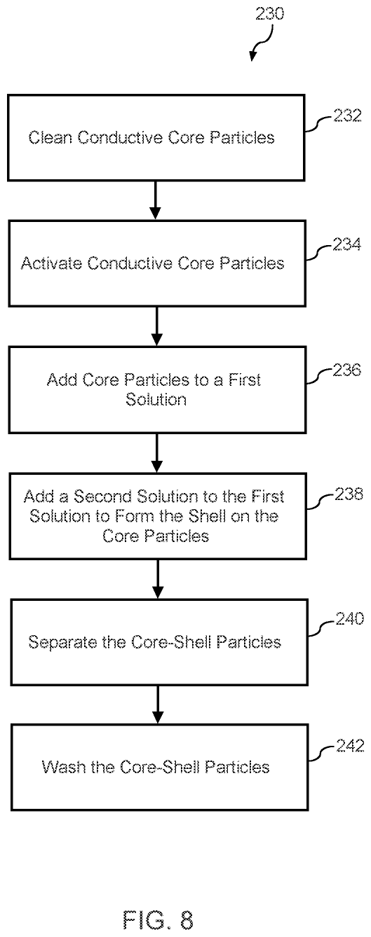

FIG. 8 depicts a flow diagram of on example method 230 of forming the core-shell particles (e.g., core-shell microparticles) of the die-attach material according to example embodiments of the present disclosure. FIG. 8 depicts example method steps for purposes of illustration and discussion. Those of ordinary skill in the art, using the disclosures provided herein, will understand that the methods described in the present disclosure may be adapted, modified, include steps not illustrated, omitted, and/or rearranged without deviating from the scope of the present disclosure.

At 232, the method 230 may include cleaning core particles. For instance, the method may include cleaning dendritic copper particles having a size of about 1 μm to about 50 μm. The core particles may be cleaned, for instance, with deionized water. In some embodiments, the core particles may be exposed to a weak acid solution (e.g., acetic acid) to remove any oxide layer on the core particles without damaging the core particles.

At 234, the method 230 may include activating the core particles. For instance, the method may include immersing in or otherwise exposing the core particles to a solution of mixed stannous chloride (SnCl₂) and palladium chloride (PdCl₂) in deionized water.

At 236, the method 230 may include adding core particles to a first solution having a reducing agent, a stabilizer, and/or a complexing agent. The first solution may be heated to a temperature in a range of about 50° C. to 60° C.

At 238, the method 210 may include adding a second solution to the first solution to form a shell on the core-shell particle. The second solution may include the shell precursor and the complementary element precursor. Examples of a shell precursor may include silver nitrate (AgNO₃), chloroauric acid (H(AuCl₄)), palladium nitrate (Pd(NO₃)₂), palladium sulfate (PdSO₄), etc. Examples of a complementary element (e.g., second element of the metal alloy) precursor may include: sodium tungstate dihydrate (Na₂WO₄), tungsten(VI) nitrate (W(NO₃)₆) cobalt nitrate (Co(NO₃)₂), cobalt sulfate (CoSO₄), sodium molybdate (Na₂MoO₄), etc. The second solution may be added to the first solution at a flow rate. The flow rate may be in a range of about 1 mL/min to about 5 mL/min. The solution may be stirred for a second process period. The second process period may be in a range of about 20 minutes to about 75 minutes. The resulting precipitate include the core-shell particles.

At 240, the core-shell particles may be separated from the solution, for instance, using a centrifuge. At 242, the core-shell particles may be washed, for instance, with deionized water or ethanol.

An example of forming core-shell particles using the method 230 of FIG. 7 is provided below:

### Example 3

### Large Copper Particles as Core

### Silver-Cobalt Alloy Shell

Dendritic copper particles (e.g., 1-50 μm) are used as core particles. The core particles are dipped into a weak acid solution (e.g., acetic acid) to remove the oxide layer without damaging the core followed by immersion in a solution of mixed stannous chloride (SnCl₂) and palladium chloride (PdCl₂) in deionized water for activation. The core particles are then washed with deionized water and added to a solution of reducing agent (NaBH₄), DMH and citric acid in deionized water at the temperature of 50° ° C. to 60° C., pH of 6.5 (adjusted using NaOH) and stirred for 2 to 10 minutes. Afterward, a solution of mixed AgNO₃ and Co(NO₃)₂ in deionized water is slowly added to the mixture (e.g., 1-5 mL/min) and stirred for another 30-60 min. The precipitate may be separated by centrifuge and washed with deionized water or ethanol.

Example aspects of the present disclosure are provided in the following paragraphs, the example of which may be combined to form various different embodiments of the present disclosure.

One example aspect of the present disclosure is directed to a die-attach material. The die-attach material may include a plurality of core-shell particles. Each core-shell particle may include a core and a shell on the core. The core may include a conducting material. The shell may include an alloy. The alloy may include a first element and a second element. The second element may segregate into one or more grain boundaries in the die-attach material during bonding of the die-attach material.

Some examples are directed to the die-attach material of any preceding paragraph, wherein the second element of the alloy reduces oxidation of the core.

Some examples are directed to the die-attach material of any preceding paragraph, wherein the die-attach material forms an intermetallic compound after bonding of the die-attach material to reduce passage of an electro-migrating metal in the die-attach material.

Some examples are directed to the die-attach material of any preceding paragraph, wherein the core includes a metal, a metal oxide, a ceramic material, or an organic material.

Some examples are directed to the die-attach material of any preceding paragraph, wherein the conducting material of the core includes copper (Cu), tin (Sn), aluminum (Al), or nickel (Ni).

Some examples are directed to the die-attach material of any preceding paragraph, wherein the first element of the alloy is silver (Ag).

Some examples are directed to the die-attach material of any preceding paragraph, wherein the second element of the alloy is tungsten (W), cobalt (Co), or molybdenum (Mo).

Some examples are directed to the die-attach material of any preceding paragraph, wherein the plurality of core-shell particles are dispersed in a solution.

Some examples are directed to the die-attach material of any preceding paragraph, wherein the solution includes ethylene glycol.

Some examples are directed to the die-attach material of any preceding paragraph, wherein the plurality of core-shell particles are grafted to a polymer matrix.

Some examples are directed to the die-attach material of any preceding paragraph, wherein the core has a size of less than about 1 μm.

Some examples are directed to the die-attach material of any preceding paragraph, wherein the core has a size in a range of about 1 μm to about 50 μm.

Some examples are directed to the die-attach material of any preceding paragraph, wherein the core includes copper (Cu) as the conducting material and the alloy includes a silver-tungsten (AgW) alloy with silver (Ag) as the first element and tungsten (W) as the second element.

Some examples are directed to the die-attach material of any preceding paragraph, wherein the core includes copper (Cu) as the conducting material and the alloy includes a silver-cobalt (AgCo) alloy with silver (Ag) as the first element and cobalt (Co) as the second element.

Some examples are directed to the die-attach material of any preceding paragraph, wherein the core includes copper (Cu) as the conducting material and the alloy includes a silver-molybdenum (AgMo) alloy with silver (Ag) as the first element and molybdenum (Mo) as the second element.

Another example aspect of the present disclosure is directed to a die-attach material. The die-attach material includes a plurality of core-shell particles. Each core-shell particle may include a core and a shell on the core. The core may include a conducting material. The shell may include an alloy. The alloy may include one or more of tungsten (W), cobalt (Co), or molybdenum (Mo).

Some examples are directed to the die-attach material of any preceding paragraph, wherein the alloy comprises silver (Ag).

Some examples are directed to the die-attach material of any preceding paragraph, wherein the core comprises copper (Cu), tin (Sn), aluminum (Al), or nickel (Ni).

Some examples are directed to the die-attach material of any preceding paragraph, the plurality of core-shell particles are dispersed in a solution.

Some examples are directed to the die-attach material of any preceding paragraph, wherein the solution comprises ethylene glycol.

Some examples are directed to the die-attach material of any preceding paragraph, wherein the plurality of core-shell particles are grafted to a polymer matrix.

Some examples are directed to the die-attach material of any preceding paragraph, wherein the core has a size of less than about 1 μm.

Some examples are directed to the die-attach material of any preceding paragraph, wherein the core has a size in a range of about 1 μm to about 50 μm.

Some examples are directed to the die-attach material of any preceding paragraph, wherein the die-attach material is lead (Pb) free.

Another example aspect of the present disclosure is directed to a device. The device may include a die including a wide band gap semiconductor material. The device may include a substrate. The device may include a die-attach material between the die and the substrate. The die-attach material may include a plurality of core-shell particles. Each core-shell particle may include a core and a shell on the core. The core may include a conducting material and the shell may include an alloy. The alloy may include one or more of tungsten (W), cobalt (Co), or molybdenum (Mo).

Some examples are directed to the device of any preceding paragraph, wherein the alloy comprises silver (Ag).

Some examples are directed to the device of any preceding paragraph, wherein the core comprises copper (Cu), tin (Sn), aluminum (Al), or nickel (Ni).

Some examples are directed to the device of any preceding paragraph, wherein the substrate comprises a conductive substrate.

Some examples are directed to the device of any preceding paragraph, wherein die comprises one or more transistor devices.

Some examples are directed to the device of any preceding paragraph, the die-attach material of claim 15, wherein the die-attach material is lead (Pb) free.

Some examples are directed to the device of any preceding paragraph, wherein the substrate comprises a lead frame.

Some examples are directed to the device of any preceding paragraph, wherein the device is a power discrete package.

Some examples are directed to the device of any preceding paragraph, wherein the device is a power module.

Another example aspect of the present disclosure is directed to a device. The device may include a substrate. The device may include a sintered material on the substrate. The sintered material may include a plurality of core-shell particles. Each core-shell particle may include a core and a shell on the core. The core may include a conducting material and the shell may include an alloy. The alloy may include a complementary element segregated into one or more grain boundaries of the sintered material.

Some examples are directed to the device of any preceding paragraph, wherein the complementary element comprises tungsten (W), cobalt (Co), or Molybdenum (Mo).

Some examples are directed to the device of any preceding paragraph, wherein the alloy comprises silver (Ag).

Some examples are directed to the device of any preceding paragraph, wherein the core comprises copper (Cu), tin (Sn), aluminum (Al), or nickel (Ni).

Some examples are directed to the device of any preceding paragraph, wherein the complementary element reduces passage of an electro-migrating metal in the sintered material.

Some examples are directed to the device of any preceding paragraph, wherein the sintered material forms a die-attach material for the device.

Some examples are directed to the device of any preceding paragraph, wherein the sintered material forms an antenna for the device.

Some examples are directed to the device of any preceding paragraph, wherein the sintered material forms an interconnect for the device.

Another example aspect of the present disclosure is directed to a method. The method may include depositing a die-attach material on a substrate. The die-attach material may include a plurality of core-shell particles. Each core-shell particle may include a core and a shell on the core. The core may include a conducting material and the shell may include an alloy. The alloy may include one or more of tungsten (W), cobalt (Co), or molybdenum (Mo). The method may include bonding the die-attach material.

Some examples are directed to the method of any preceding paragraph, wherein bonding the die-attach material comprises bonding the die-attach material at a temperature in a range of about 100° C. to about 400° C.

Some examples are directed to the method of any preceding paragraph, wherein bonding the die-attach material comprises bonding the die-attach material for a time period in a range of about 30 minutes to about 120 minutes.

Some examples are directed to the method of any preceding paragraph, wherein bonding the die-attach material comprises bonding the die-attach material at a pressure in a range of about 1 MPa to about 30 MPa.

Some examples are directed to the method of any preceding paragraph, wherein depositing a die-attach material on the substrate comprises depositing the die-attach material by one or more of an inkjet, screen printer, flexo printer, gravure printer, spin coater, blade coater, or spray coater.

Some examples are directed to the method of any preceding paragraph, wherein bonding the die-attach material comprises sintering the die-attach material.

Some examples are directed to the method of any preceding paragraph, wherein bonding the die-attach material comprises bonding the die-attach material with a laser.

Some examples are directed to the method of any preceding paragraph, wherein bonding the die-attach material comprises bonding the die-attach material with pulsed light.

Some examples are directed to the method of any preceding paragraph, wherein bonding the die-attach material forms an antenna or an interconnect on the substrate.

Some examples are directed to the method of any preceding paragraph, wherein bonding the die-attach material attaches a semiconductor die to the substrate.

Some examples are directed to the method of any preceding paragraph, wherein the alloy comprises silver (Ag).

Some examples are directed to the method of any preceding paragraph, wherein the core comprises copper (Cu), tin (Sn), aluminum (Al), or nickel (Ni).

Another example aspect of the present disclosure is directed to a method. The method may include adding a second solution to a first solution. The first solution may include a core particle. The second solution may include a shell precursor and a complementary element precursor to form a shell on the core particle. The shell may include an alloy. The alloy may include tungsten (W), cobalt (Co), or molybdenum (Mo).

Some examples are directed to the method of any preceding paragraph, wherein the core is formed from a core precursor.

Some examples are directed to the method of any preceding paragraph, wherein the core precursor comprises one or more of copper sulfate (CuSO₄), copper nitrate (Cu(NO₃)₂), copper chloride (CuCl₂), copper acetate (Cu(CO₂CH₃)₂), nickel acetate (Ni(CH₃CO₂)₂), nickel sulfate (NiSO₄).

Some examples are directed to the method of any preceding paragraph, wherein the shell precursor comprises one or more of silver nitrate (AgNO₃), chloroauric acid (H(AuCl₄)), palladium nitrate (Pd(NO₃)₂), palladium sulfate (PdSO₄).

Some examples are directed to the method of any preceding paragraph, wherein the complementary element precursor comprises one or more of sodium tungstate dihydrate (Na₂WO₄), tungsten(VI) nitrate (W(NO₃)₆) cobalt nitrate (Co(NO₃)₂), cobalt sulfate (CoSO₄), sodium molybdate (Na₂MoO₄).

Some examples are directed to the method of any preceding paragraph, wherein the first solution comprises a reducing agent.

Some examples are directed to the method of any preceding paragraph, wherein the reducing agent comprises one or more of ethylene glycol (EG), sodium borohydride (NaBH₄), Monosodium phosphate (NaH₂PO₄), glucose (C₆H₁₂O₆), dimethylamine-borane (DMAB), ascorbic acid (C₆H₈O₆), or polyvinylpyrrolidone (PVP).

Some examples are directed to the method of any preceding paragraph, wherein first solution comprises a stabilizer.

Some examples are directed to the method of any preceding paragraph, where the stabilizer comprises one or more of polyvinylpyrrolidone (PVP), cetyltrimethylammonium-bromide (CTAB), ethylenediamin (EDA), or dimethylhydentoine (DMH).

Some examples are directed to the method of any preceding paragraph, wherein the method includes heating a base solution of a stabilizer and reducing agent to a first temperature; and adding a core precursor to the base solution to form the first solution.

Some examples are directed to the method of any preceding paragraph, wherein first temperature is in a range of about 50° C. to about 100° C.

Some examples are directed to the method of any preceding paragraph, wherein the method includes heating the first solution with the core precursor to a second temperature and maintaining the first solution at about the second temperature for a process period to form the core.

Some examples are directed to the method of any preceding paragraph, wherein the second temperature is in a range of about 100° ° C. to about 175° C.

Some examples are directed to the method of any preceding paragraph, wherein the process period is in a range of about 5 minutes to about 30 minutes.

Some examples are directed to the method of any preceding paragraph, wherein adding a second solution to a first solution comprises adding the second solution to the first solution at a flow rate in a range of about 1 mL/min to about 5 mL/min.

Some examples are directed to the method of any preceding paragraph, wherein the method comprises activating the core particle with a mixture of stannous chloride (SnCl₂) and palladium chloride (PdCl₂).

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A die-attach material, comprising:
a plurality of core-shell particles, each core-shell particle comprising a core and a shell on the core;
wherein the core comprises a conducting material;
wherein shell comprises an alloy, the alloy comprising a first element and a second element, wherein the second element segregates into one or more grain boundaries in the die-attach material during bonding of the die-attach material.

2. The die-attach material of claim 1, wherein the second element of the alloy reduces oxidation of the core.

3. The die-attach material of claim 1, wherein the die-attach material forms an intermetallic compound after bonding of the die-attach material to reduce passage of an electro-migrating metal in the die-attach material.

4. The die-attach material of claim 1, wherein the core comprises a metal, a metal oxide, a ceramic material, or an organic material.

5. The die-attach material of claim 1, wherein the conducting material of the core comprises copper (Cu), tin (Sn), aluminum (Al), or nickel (Ni).

6. The die-attach material of claim 1, wherein the first element of the alloy is silver (Ag).

7. The die-attach material of claim 1, wherein the second element of the alloy is tungsten (W), cobalt (Co), or molybdenum (Mo).

8. The die-attach material of claim 1, wherein the plurality of core-shell particles are dispersed in a solution.

9. The die-attach material of claim 8, wherein the solution comprises ethylene glycol.

10. The die-attach material of claim 1, wherein the plurality of core-shell particles are grafted to a polymer matrix.

11. The die-attach material of claim 1, wherein the core has a size of less than about 1 μm.

12. The die-attach material of claim 1, wherein the core has a size in a range of about 1 μm to about 50 μm.

13. The die-attach material of claim 1, wherein the core comprises copper (Cu) as the conducting material and the alloy comprises a silver-tungsten (AgW) alloy with silver (Ag) as the first element and tungsten (W) as the second element.

14. The die-attach material of claim 1, wherein the core comprises copper (Cu) as the conducting material and the alloy comprises a silver-cobalt (AgCo) alloy with silver (Ag) as the first element and cobalt (Co) as the second element.

15. The die-attach material of claim 1, wherein the core comprises copper (Cu) as the conducting material and the alloy comprises a silver-molybdenum (AgMo) alloy with silver (Ag) as the first element and molybdenum (Mo) as the second element.

16. A die-attach material, comprising:
a plurality of core-shell particles, each core-shell particle comprising a core and a shell on the core;
wherein the core comprises a conducting material and the shell comprises an alloy;
wherein the alloy comprises one or more of tungsten (W), cobalt (Co), or molybdenum (Mo).

17. The die-attach material of claim 16, wherein the alloy comprises silver (Ag).

18. The die-attach material of claim 16, wherein the core comprises copper (Cu), tin (Sn), aluminum (Al), or nickel (Ni).

19. The die-attach material of claim 16, the plurality of core-shell particles are dispersed in a solution.

20.-24. (canceled)

25. A device, comprising:
a die comprising a wide band gap semiconductor material;
a substrate;
a die-attach material between the die and the substrate, the die-attach material comprising a plurality of core-shell particles, each core-shell particle comprising a core and a shell on the core;
wherein the core comprises a conducting material and the shell comprises an alloy;
wherein the alloy comprises one or more of tungsten (W), cobalt (Co), or molybdenum (Mo).

26.-69. (canceled)
